(19) United States
(12) Patent Application Publication
(10) Pub. No.: US 2023/0370045 A1
(43) Pub. Date: Nov. 16, 2023

(54) HIGH-EFFICIENCY ACOUSTIC EXCITATION LOW-FREQUENCY ANTENNA DRIVEN BY SERIAL ELECTRODES

(71) Applicant: Anhui University, Hefei (CN)

(72) Inventors: Yingsong LI, Hefei (CN); Lulu MENG, Hefei (CN); Zhixiang HUANG, Hefei (CN)

(21) Appl. No.: 18/098,480

(22) Filed: Jan. 18, 2023

(30) Foreign Application Priority Data
May 11, 2022 (CN) 202210513114.0

(51) Int. Cl. H03H 9/13; H01Q 1/50; H03H 9/17

(52) U.S. Cl. CPC H03H 9/13; H01Q 1/50; H03H 9/17

(57) ABSTRACT

Disclosed is a high-efficiency acoustic excitation low-frequency antenna driven by serial electrodes, including a plurality of electrode driving units for generating enhanced mechanical vibration waves based on voltage driving, a plurality of electrode isolation insulators positioned between every two electrode driving units to prevent short circuit between the electrode driving units, a mechanical-electromagnetic field conversion unit used for converting the enhanced mechanical vibration waves into enhanced electromagnetic field radiation and improving receiving sensitivity based on the enhanced electromagnetic field radiation, and electrode constraint structures used for constraining the electrode driving units so that the electrode driving units are located in the electrode constraint structures.

### CROSS-REFERENCE TO RELATED APPLICATIONS

This application claims priority to Chinese Patent Application No. 202210513114.0, filed on May 11, 2022, the contents of which are hereby incorporated by reference.

### TECHNICAL FIELD

The application belongs to the field of low-frequency antenna design, and in particular to a high-efficiency acoustic excitation low-frequency antenna driven by serial electrodes.

### BACKGROUND

The conventional low-frequency antenna is mainly a metal antenna designed according to the principle of conductor-current. The size of the antenna is equivalent to a half wavelength of the resonance frequency of the center frequency, which leads to the large size of the antenna, the difficulty in installation and the inability to integrate with the equipment terminal. In addition, with the development of multi-domain communication, the demands of individual soldier, piggyback, personal communication and satellite communication, human communication and regional networking have made low-frequency communication become one of the hot issues in current development. Also, low-frequency communication may be used as an interconnection communication mode of deep-sea communication to realize the interconnection of sea and air, and is also one of the main means of beyond-line-of-sight (BLOS) communication, detection and underground communication. Especially in recent years, the research of low frequency in aircraft, medical monitoring, etc. has attracted wide attention of scholars at home and abroad, so the research of low-frequency antenna is increasing and the demand is increasing. Meanwhile, with the development of antenna miniaturization, the research of low-frequency antenna is also developing towards miniaturization and light weight. However, the miniaturization of low-frequency antenna inevitably reduces the gain and efficiency of the antenna. Therefore, it is urgent to develop a miniaturized low-frequency high-efficiency antenna to improve the gain and reduce efficiency loss in the process of miniaturization of low-frequency antenna, so that the high-efficiency design of miniaturized low-frequency antenna is achieved to lay a foundation for applying the miniaturized low-frequency antenna extensively.

### SUMMARY

The objective of the present application is to provide a high-efficiency acoustic excitation low-frequency antenna driven by serial electrodes to solve the problems existing in the prior art.

To achieve the above objective, the present application provides a high-efficiency acoustic excitation low-frequency antenna driven by serial electrodes, including:
a plurality of electrode driving units, a plurality of electrode isolation insulators, a mechanical-electromagnetic field conversion unit and electrode constraint structures,
where the electrode driving units generate mechanical vibration waves by voltage excitation; in other words, the voltage drives electrode units to generate enhanced mechanical vibration waves;
the electrode isolation insulators are positioned between every two electrode driving units and used for preventing short circuit between the electrode driving units;
the mechanical-electromagnetic field conversion unit is used for generating enhanced electromagnetic field radiation based on driving of the mechanical vibration waves, and improving receiving sensitivity based on the enhanced electromagnetic field radiation;
the electrode constraint structures are used for constraining the electrode driving units so that the electrode driving units are located in the electrode constraint structures.

Optionally, a plurality of the electrode driving units adopt a serial structure and generate the enhanced mechanical vibration waves through the serial structure.

Optionally, the electrode driving units include positive electrodes and negative electrodes, and piezoelectric materials are filled between the positive electrodes and the negative electrodes, and the piezoelectric materials are used for generating the mechanical vibration waves based on the voltage excitation.

Optionally, the electrode driving units are connected to the electrode constraint structures, and the electrode constraint structures include a positive electrode constraint structure and a negative electrode constraint structure;

the electrode driving units each include the positive electrodes and the negative electrodes at both ends, one end of each positive electrode is connected to the positive electrode constraint structure, and one end of each negative electrode is connected to the negative electrode constraint structure.

Optionally, the one end of each positive electrode is connected to the positive electrode constraint structure as follows:
one end of each positive electrode in all the electrode driving units is connected to the positive electrode constraint structure, and the other end of the each positive electrode in all the electrode driving units is not connected to the negative electrode constraint structure.

Optionally, the one end of each negative electrode is connected to the negative electrode constraint structure as follows:
one end of each negative electrode in all the electrode driving units is connected to the negative electrode constraint structure, a direction of the one end of each negative electrode connected to the electrode constraint structure is the same as that of the one end of each positive electrode not connected to the electrode constraint structure, and the other end of the each negative electrode is not connected to the electrode constraint structure.

Optionally, the number of the electrode driving units is determined by an electromagnetic radiation intensity requirement.

The application has following technical effects.

The high-efficiency acoustic excitation low-frequency antenna driven by the serial electrode provided in the application improves the gain and efficiency of an miniaturized electrode antenna, so that the designed high-efficiency acoustic excitation low-frequency antenna driven by the serial electrode not only has the characteristics of miniaturization, but also adjusts the gain and efficiency of the antenna according to requirements, so that the gain is controllable.

### BRIEF DESCRIPTION OF THE DRAWINGS

The drawings that form a part of this application are used to provide a further understanding of this application, and the illustrative embodiments and descriptions of this application are used to explain this application, without unduly limiting it.

FIG. 1 is a front view of a high-efficiency acoustic excitation low-frequency antenna driven by serial electrodes in an embodiment of the present application.

FIG. 2 is a top view of a high-efficiency acoustic excitation low-frequency antenna driven by serial electrodes in an embodiment of the present application.

### DETAILED DESCRIPTION OF THE EMBODIMENTS

It should be noted that the embodiments in this application and the features in the embodiments may be combined with each other without conflict. The application will be described in detail with reference to the drawings and examples.

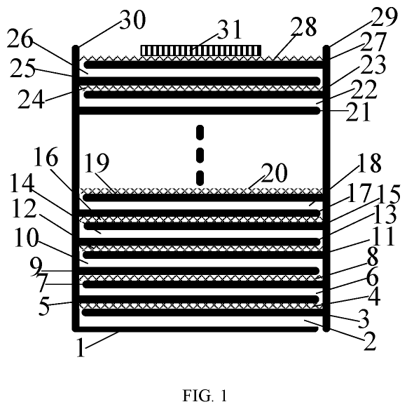

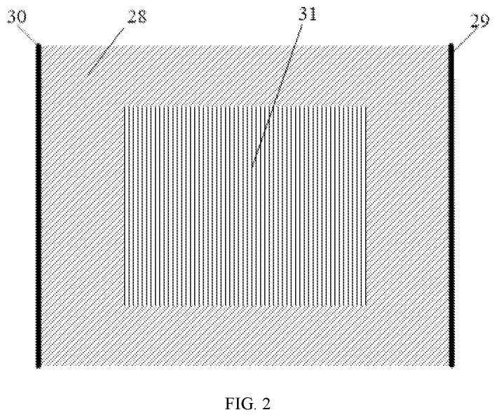

as shown in FIG. 1-FIG. 2, a high-efficiency acoustic excitation low-frequency antenna driven by serial electrodes provided by this embodiment includes a plurality of pairs of serial positive and negative electrodes, constraint structures, electrode isolation insulators, piezoelectric materials, and a mechanical-electromagnetic field conversion unit, where the positive electrodes of the pairs of serial positive and negative electrodes are connected to a positive pole of a power supply, and the negative electrodes are connected to a negative pole of the power supply, and the positive and negative electrodes have certain gaps from a negative constraint structure and a positive constraint structure respectively. All positive electrodes are connected and have certain gaps from the negative electrode constraint structure and are connected to the positive pole of the power supply with same voltage. All the negative electrodes are connected and have certain gaps from the positive electrode constraint structure and are connected to the negative pole of the power supply. As shown in FIG. 1, 1, 5, 9, 13, 17, 21 and 25 are the positive electrodes, 21 is a (N−1)-th positive electrode, 25 is an N-th positive electrode, while 3, 7, 11, 5, 19, 23 and 27 are the negative electrodes, 23 is a (N−1)-th negative electrode, 27 is an N-th negative electrode, and 2, 6, 10, 14, 18, 22 and 26 are piezoelectric materials, where 22 is a (N−1)-th piezoelectric material, and 26 is an N-th piezoelectric material; 4, 8, 12, 16, 20, 24, and 28 are the electrode isolation insulators, where 24 and 28 are (N−1)-th and N-th electrode isolation insulators; 29 and 30 are the negative electrode constraint structure and the positive electrode constraint structure, respectively, and 31 is the mechanical-electromagnetic field conversion unit.

The positive and negative electrodes include a first positive and negative electrode, a second positive and negative electrode, a third positive and negative electrode, a fourth positive and negative electrode . . . an N-th positive and negative electrode.

The piezoelectric materials include a first piezoelectric material, a second piezoelectric material, a third piezoelectric material, a fourth piezoelectric material . . . an N-th piezoelectric material.

The electrode isolation insulators include a first electrode isolation insulator, a second electrode isolation insulator, a third electrode isolation insulator, a fourth electrode isolation insulator . . . an N-th electrode isolation insulator.

1 is the first positive electrode, 2 is the first piezoelectric material, and 3 is the first negative electrode, and 1, 2 and 3 constitute a first electrode driving unit, and 4 is the first electrode isolation insulator. By analogy, the antenna consists of N electrode driving units closely connected to form serial electrode driving structure of the antenna. N groups of electrode driving units are driven by voltage to drive the piezoelectric materials inside electrodes to be converted into acoustic resonance, and generate mechanical vibration waves. The electrode isolation insulators are used among the N groups of electrode driving units to prevent short circuit between electrodes. Through serial driving of the N groups of electrode driving units, the generated mechanical vibration waves are converted into electromagnetic radiation by the mechanical-electromagnetic field conversion unit.

N pairs of electrodes drive N piezoelectric materials to form N pairs of acoustic resonance structures, and generate enhanced acoustic waves to drive the only mechanical-electromagnetic field conversion unit to convert the mechanical waves to electromagnetic waves.

The number N of positive and negative electrode pairs and the number N of piezoelectric materials in the acoustic resonance structures is determined according to an allowable electromagnetic radiation intensity of a system.

The piezoelectric materials are driven by serial voltage, and serial electric field generated by the serial voltage drives a plurality of piezoelectric materials to generate acoustic resonance, and the vibration is transmitted to the mechanical-electromagnetic field conversion unit, so that the acoustic wave is enhanced and converted into enhanced electromagnetic waves by the mechanical-electromagnetic field conversion unit for radiation.

The mechanical-electromagnetic field conversion unit is used for enhancing the resonance of mechanical vibration waves to obtain enhanced electromagnetic waves.

Serial voltage driving effectively enhances the acoustic wave intensity, and finally enhances the electromagnetic wave intensity, thus realizing a design of high-efficiency acoustic excitation low-frequency antenna.

The serial electrode driving structure is serially connected by N groups of electrode driving units, and the electrode isolation insulators are adopted among electrodes to avoid short circuit. Through the serial resonance of N groups of electrode driving units, the acoustic waves generated by electrode driving are enhanced, and the vibration amplitude of mechanical waves is further enhanced, so that field strength of the electromagnetic wave obtained by the mechanical-electromagnetic field conversion unit is enhanced, and thus the high-efficiency acoustic excitation antenna is realized.

The N pairs of positive and negative electrodes have the same supply voltage, and the thicknesses of piezoelectric materials and the electrode isolation insulators are the same, and the positive and the negative electrodes have certain gaps from the negative and positive constraint structures, respectively, to avoid short circuits.

A serial electrode feeding mechanism, electrode isolation insulators, and serial electrodes jointly driving the mechanical-electromagnetic field conversion unit adopted by the application aim to improve the conversion efficiency of voltage-acoustic wave-mechanical wave-electromagnetic wave and improve the signal receiving sensitivity. In addition, the designed antenna is small in size, and compared with a metal antenna in the same size, the designed antenna has high gain and high efficiency, and is allowed to be flexibly installed. The designed high-efficiency acoustic excitation low-frequency antenna driven by serial electrode is completely different from the conventional low-frequency antenna in terms of principle. The application adopts serial electrode driving, which provides a new method for the design of high-efficiency acoustic excitation low-frequency antenna.

According to the high-efficiency acoustic excitation low-frequency antenna driven by serial electrodes, the piezoelectric material is excited by voltage, so that the piezoelectric material generates acoustic resonance, and then generates mechanical vibration, which is converted into a radiation field by a mechanical-electromagnetic field conversion unit, and the amplitude of the acoustic field is enhanced by the same structural unit driven by the same voltage in a serial structure, so that the gain of the antenna is further enhanced by the mechanical-electromagnetic field conversion unit, and the efficiency of the antenna is improved; and all units of the antenna are fixed by the constraint structures, so that all antenna units are integrated organically, and the design of the high-efficiency low-frequency antenna is realized. According to the application, a plurality of piezoelectric materials are excited by the way of serial voltage feeding, and the vibration is enhanced by the transmission of the vibration of the serial piezoelectric materials, and the strong vibration is transmitted to the mechanical-electromagnetic field conversion unit, and the mechanical-electromagnetic field conversion unit converts the strong vibration of the plurality of piezoelectric materials excited by the serial voltage feeding into strong electromagnetic waves for radiation, thereby enhancing the radiation intensity of electromagnetic waves and being beneficial to improving the gain and efficiency of the antenna. In addition, in order to prevent the short-circuit problem caused by the close contact among a plurality of electrodes, the application puts forward a design mode of electrode isolation insulators, which can not only transmit the vibration of piezoelectric materials in a plurality of electrodes to the mechanical-electromagnetic field conversion unit to form electromagnetic radiation, but also realize the miniaturization and high-gain design of the antenna. Because the designed antenna adopts the form of serial voltage feeding, the gain of the antenna is greatly improved compared with that of the conventional antenna with the same size, and the antenna size is reduced to millimeter level, with at least 5 orders of magnitude shorter than that of the metal antenna with the same size.

The high-efficiency acoustic excitation low-frequency antenna driven by the serial electrodes designed by the application has high gain and efficiency, and small size, and is convenient to be integrated in aircraft, satellites, individual soldier piggyback systems, frogmen and other equipment, so as to realize the interconnection and intercommunication among air, sky and sea and multi-domain communication and solve problems of large volume leading to failure in integrating with air equipment, low gain and efficiency, etc. of the conventional metal antenna, so the high-efficiency acoustic excitation low-frequency antenna driven by the serial electrodes not only integrates with air, sky and sea equipment in an integrated way, but also reduces the weight of equipment. Meanwhile, the designed low-frequency antenna is also allowed to be applied to mobile terminals, providing a new solution for the interconnection of mobile terminals and car networking, and even providing an effective wireless transmission scheme for the integrated design of family medical care.

The above are only the preferred embodiments of this application, but the scope of protection of this application is not limited to this. Any changes or substitutions that can be easily thought of by those skilled in the technical field within the technical scope disclosed in this application should be covered by the scope of protection of this application. Therefore, the scope of protection of this application should be based on the scope of protection of the claims.

What is claimed is:

1. A high-efficiency acoustic excitation low-frequency antenna driven by serial electrodes, comprising:
a plurality of electrode driving units, a plurality of electrode isolation insulators, a mechanical-electromagnetic field conversion unit and electrode constraint structures,
wherein the electrode driving units generate mechanical vibration waves based on voltage excitation;
the electrode isolation insulators are positioned between every two electrode driving units and used for preventing short circuits between the electrode driving units;
the mechanical-electromagnetic field conversion unit is used for generating enhanced electromagnetic field radiation based on driving of the mechanical vibration waves, and improving receiving sensitivity based on the enhanced electromagnetic field radiation;
the electrode constraint structures are used for constraining the electrode driving units so that the electrode driving units are located in the electrode constraint structures;
a plurality of the electrode driving units adopt a serial structure and generate enhanced mechanical vibration waves through the serial structure;
the electrode driving units comprise positive electrodes and negative electrodes, and piezoelectric materials are filled between the positive electrodes and the negative electrodes, and the piezoelectric materials are used for generating the mechanical vibration waves based on the voltage excitation;
the electrode driving units are connected to the electrode constraint structures, and the electrode constraint structures comprise a positive electrode constraint structure and a negative electrode constraint structure;
the electrode driving units each comprise the positive electrodes and the negative electrodes at both ends, one end of each positive electrode is connected to the positive electrode constraint structure, and one end of each negative electrode is connected to the negative electrode constraint structure;
the one end of each positive electrode is connected to the positive electrode constraint structure as follows:
one end of each positive electrode in all the electrode driving units is connected to the positive electrode constraint structure, and the other end of each positive electrode in all the electrode driving units is not connected to the negative electrode constraint structure; and
the one end of each negative electrode is connected to the negative electrode constraint structure as follows:
one end of each negative electrode in all the electrode driving units is connected to the negative electrode constraint structure, a direction of the one end of each negative electrode connected to the electrode constraint structure is same as that of the one end of each positive electrode not connected to the electrode constraint structure, and the other end of the each negative electrode is not connected to the electrode constraint structure.

2. The high-efficiency acoustic excitation low-frequency antenna driven by serial electrodes according to claim 1, wherein a number of the electrode driving units is determined by an electromagnetic radiation intensity requirement.
